(19) United States
(12) Patent Application Publication
(10) Pub. No.: US 2026/0016504 A1
(43) Pub. Date: Jan. 15, 2026

(54) TEST DEVICE

(71) Applicant: SILICONWARE PRECISION INDUSTRIES CO., LTD., Taichung City (TW)

(72) Inventors: Hsien-Jui SYU, Taichung City (TW); Po-Wen HSIAO, Taichung City (TW); Wen-Chin LIANG, Taichung City (TW)

(73) Assignee: SILICONWARE PRECISION INDUSTRIES CO., LTD., Taichung City (TW)

(21) Appl. No.: 18/930,561

(22) Filed: Oct. 29, 2024

(30) Foreign Application Priority Data
Jul. 15, 2024 (TW) 113126459

(51) Int. Cl. G01R 1/073

(52) U.S. Cl. CPC G01R 1/07364; G01R 1/07342

(57) ABSTRACT

A test device including a guide plate structure, a shunt structure coupled to the guide plate structure, and a plurality of probes penetrating the guide plate structure and the shunt structure. A side of the guide plate structure is coupled to a circuit board, and another side is coupled to a device under test. The shunt structure has a metal material and thus can provide additional routes for the current, thereby melting caused by excessive current passing through due to abnormality of the probes per se can be prevented.

### BACKGROUND

### 1. Technical Field

The present disclosure relates to a test device, and more particularly, to a test device for a probe card.

### 2. Description of Related Art

In traditional wafer testing, the test signal is input into the integrated circuit of the device under test (DUT). The main method is to touch the soldering pads (or bumps) of the device under test with a plurality of tiny probes in the probe card, and test signals are sent from the test machine to the integrated circuit through the probes and soldering pads (or bumps). After processed by the integrated circuit, the test signals are then fed back to the test machine through the probes, and the test machine analyze the feedback signals to achieve the results of wafer testing.

Furthermore, in recent years, the design of chips has gradually developed towards high density and high current, then the operating temperature of the chip has increased significantly along with the current density under this demand. However, during wafer testing, the testing machine performs the electrical testing with a current of 150 mA to 2A passing through the probe, the abnormal problems such as burning needles and bent needles may occurred due to instantly excessive current caused by electric heating (high temperature), metal fatigue, dirt or deformation of the probe itself, and thus the operation time and availability are seriously affected.

Therefore, how to overcome the above-mentioned problems of conventional techniques has become an urgent issue to be solved.

### SUMMARY

In view of the aforementioned shortcomings of the prior art, the present disclosure provides a test device including: a guide plate structure; a shunt structure coupled to the guide plate structure; and a plurality of probes penetrating the guide plate structure and the shunt structure, in a manner that the shunt structure contacts with a part of the plurality of probes to provide a current shunting route.

In the aforementioned test device, a side of the guide plate structure is coupled to a circuit board, and another side is coupled to a device under test.

In the aforementioned test device, the guide plate structure includes a first guide plate and a second guide plate, and the first guide plate and the second guide plate are arranged in parallel with each other and are separated from each other by a gap.

In the aforementioned test device, a plurality of first openings are formed in the first guide plate, a plurality of second openings are formed in the second guide plate, and the plurality of first openings correspond in position to the plurality of second openings, respectively, to slidingly accommodate the plurality of probes.

In the aforementioned test device, wherein each of the probes includes a stroke section, a test section and a switching section that extend from two sides of the stroke section; the stroke section is located at the gap between the first guide plate and the second guide plate, and the stroke section is formed in a bent shape, and thus has functions of absorbing external forces and stroke; the test section extends from one end of the stroke section and passes through the first guide plate, so as to couple the test section to the device under test; the switching section extends from the other end of the stroke section and passes through the second guide plate, so as to couple the switching section to the circuit board.

In the aforementioned test device, the shunt structure is disposed in the first guide plate or is disposed between the first guide plate and the second guide plate.

In the aforementioned test device, the shunt structure is defined with at least one first area and at least one second area, the at least one first area is an insulation material and has a plurality of first through holes, the at least one second area is a metal material and has a plurality of second through holes, and the plurality of probes are disposed through the plurality of first through holes and the plurality of second through holes.

In the aforementioned test device, the plurality of probes disposed through the plurality of the first through holes are used to test a signal, the plurality of probes disposed through the plurality of second through holes are used to test a power.

By implementation of the present disclosure, the test device includes the guide plate structure, the shunt structure coupled to the guide plate structure and the plurality of probes penetrating the guide plate structure and the shunt structure, and the shunt structure is mainly added within or outside the guide plate structure. Therefore, a shunt path can be provided through the metal material in the shunt structure contacted with the part of the plurality of probes when an electrical current related abnormality occurs, to avoid the melting caused by the excessive current passing through due to abnormalities of the probes themselves, or the electrical test results being affected by the opening of the probes.

### BRIEF DESCRIPTION OF THE DRAWINGS

FIG. 1A and FIG. 1B are schematic cross-sectional views of an application of a first embodiment of the test device of the present disclosure.

FIG. 2 is a schematic top view of the shunt structure of the test device of the present disclosure.

FIG. 3A and FIG. 3B are schematic cross-sectional views of an application of a second embodiment of the test device of the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

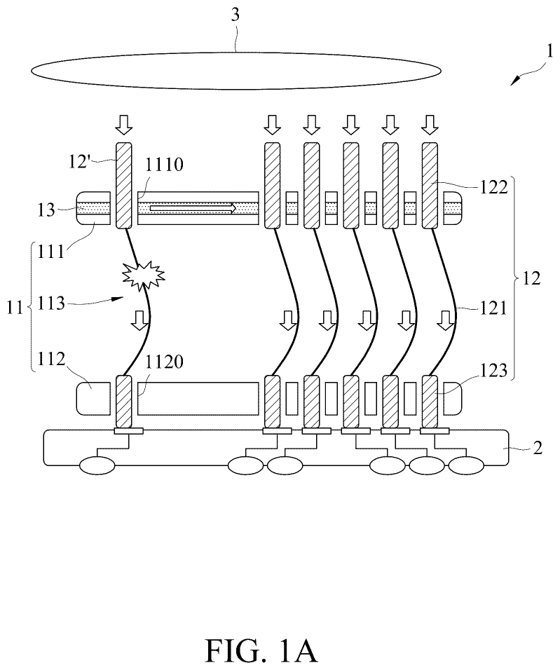

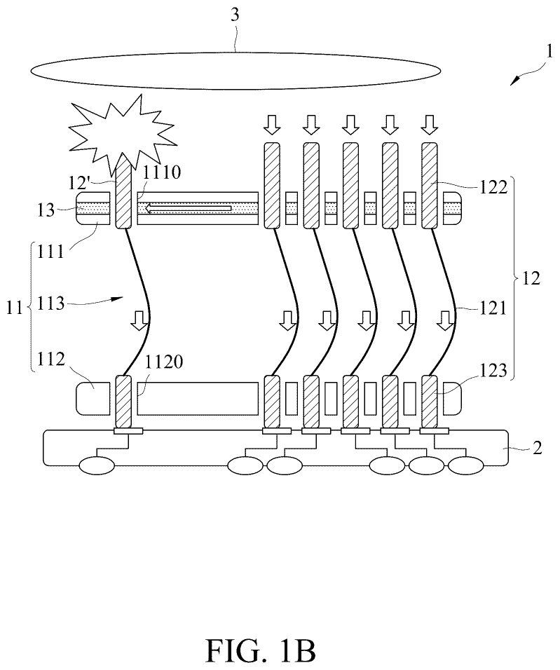

Please refer to FIG. 1A and FIG. 1B, which are schematic cross-sectional views of a first embodiment of an application of a test device 1 of the present disclosure. The test device 1 includes: a guide plate structure 11, a plurality of probes 12 and a shunt structure 13.

A side of the guide plate structure 11 is coupled to a circuit board 2, and another side is coupled to a device under test (DUT) 3. The plurality of probes 12 are disposed pass through the guide plate structure 11, and are electrically connected to the circuit board 2, thereby test signals are transmitted to the device under test 3. The device under test 3 is, for example, a wafer/chip.

In this embodiment, the guide plate structure 11 includes a first guide plate 111 and a second guide plate 112. The first guide plate 111 and the second guide plate 112 are arranged in parallel with each other and are separated from each other by a gap 113. A plurality of first openings 1110 and a plurality of second openings 1120 are formed in the first guide plate 111 and the second guide plate 112, respectively, and the plurality of first openings 1110 are corresponding in position to the plurality of second openings 1120, respectively. The first openings 1110 and the second openings 1120 may be positioned aligned with each other or dislocated with a distance, to slidingly accommodate the plurality of probes 12.

The plurality of probes 12 are, for example, probes of vertical type, and each of the probes 12 includes a stroke section 121, a test section 122 and a switching section 123 that extend from two sides of the stroke section 121, respectively. The stroke section 121 is located at the gap 113 between the first guide plate 111 and the second guide plate 112, and the stroke section 121 is formed in a bent shape and thus has the abilities of absorbing external forces and stroke.

The test section 122 extends from one end of the stroke section 121 and passes through the first guide plate 111 to connect to the device under test 3. The test section 122 contacts with the pad or bump on the device under test 3 (wafer/chip) to elicit signals of the device under test, and send information of the signals to the test machine for analysis and identification.

The switching section 123 extends from another end of the stroke section 121 and passes the second guide plate 112, to couple the switching section 123 to the circuit board 2.

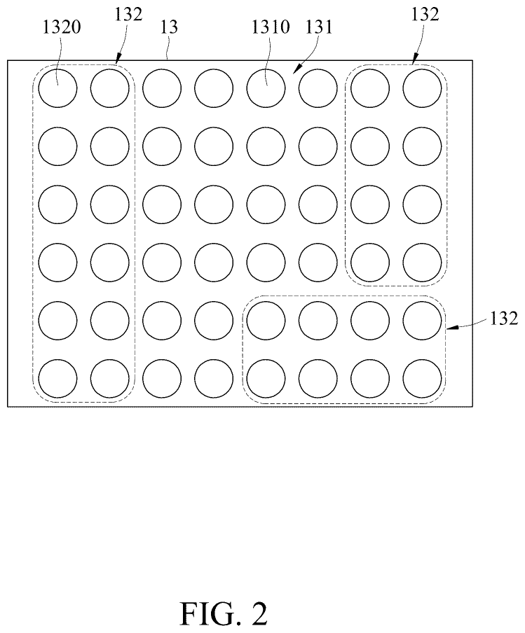

Please also refer to FIG. 2 simultaneously, the shunt structure 13 is disposed within the first guide plate 111 to contact with the test section 122 of the plurality of probes 12. In this embodiment, the shunt structure 13 is a plate-shaped structure defined with at least one first area 131 and at least one second area 132 (only one first area 131 and three second areas 132 are shown in this embodiment). A plurality of first through holes 1310 and second through holes 1320 are disposed on the at least one first area 131 and the at least one second area 132, respectively, for the plurality of probes 12 passing through. The first area 131 of the shunt structure 13 is formed in an insulation material and has the plurality of first through holes 1310, and the probes 12 passing through the plurality of the first through holes 1310 are used for testing signals. In addition, the second area 132 of the shunt structure 13 is formed in a metal material and has the plurality of second through holes 1320, and the probes 12 passing through the plurality of second through holes 1320 are used for testing power.

In this embodiment, the shunt structure 13 is disposed in the first guide plate 111, which has the advantage of avoiding the short problem due to peeling off of the coating layer and sticking of external sand.

As shown in FIG. 1A, in an application scenario, if the impedance(s) of one or a part of the probes 12′ is/are large due to the damage(s), the current passed can be shunted to other probes 12 that are not damaged through the shunt structure 13 disposed in the first guide plate 111 to contact with the other probes 12 that are not damaged, to avoid the ablation problem of the aforementioned damaged probe(s) 12′.

As shown in FIG. 1B, in another application scenario, if no current passes through one or a part of the probes 12′ due to an open status, the passing current can be shunted to the aforementioned probe(s) 12′ through the shunt structure 13 disposed in the first guide plate 111 to contact with the other probes 12, and thus the current can pass through the aforementioned probe(s) 12′.

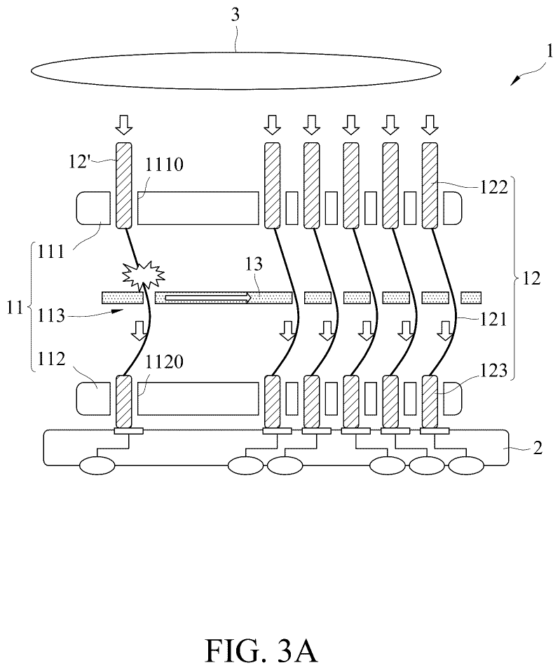

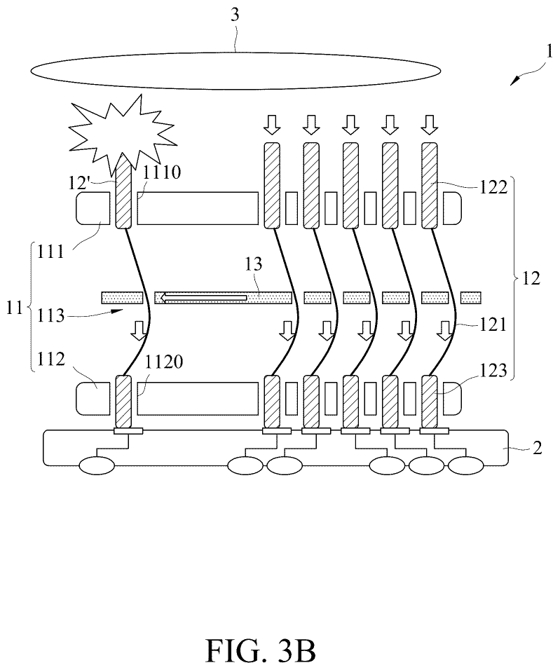

Please refer to FIG. 3A and FIG. 3B, which are the schematic cross-sectional views of a second embodiment of an application of the test device of the present disclosure. The present embodiment is roughly the same as the aforementioned embodiment, and the same parts are omitted. The main difference is that the shunt structure 13 in the present embodiment is disposed between the first guide plate 111 and the second guide plate 112, and contacts with the stroke section 121 of the probe 12.

The shunt structure 13 in this embodiment is in a metallic film structure, whose top view is shown as FIG. 2. It is also defined with the first area 131 and the second area 132, wherein the first area 131 is formed in an insulation material and has a plurality of first through holes 1310, and the probes 12 passing through the plurality of first through holes 1310 are used for signal test. The second area 132 is in a metal material and has a plurality of second through holes 1320, and the probes 12 passing through the plurality of second through holes 1320 are used for power test.

The shunt structure 13 in this embodiment is disposed between the first guide plate 111 and the second guide plate 112, which has the advantages of low cost and being easy to be replaced.

As shown in FIG. 3A, if the impedance(s) of one or a part of the probes 12′ is/are large due to the damage(s), the current passed can be shunted to other probes 12 that are not damaged through the shunt structure 13 disposed between the first guide plate 111 and the second guide plate 112, to avoid the ablation problem of the aforementioned damaged probe(s) 12′. In addition, as shown in FIG. 3B, if no current passes through one or a part of the probes 12′ due to that an open status, the passing current can be shunted to the aforementioned probe(s) 12′ through the shunt structure 13 disposed between the first guide plate 111 and the second guide plate 112, and thus the current can pass through the aforementioned probe(s) 12′.

Therefore, the test device of the present disclosure includes a guide plate structure, a shunt structure combined with the guide plate structure and a plurality of probes passing through the guide plate structure and the shunt structure, and the shunt structure is mainly added within or outside the guide plate structure. Therefore, a shunt path for the current can be provided through the metal material in the shunt structure contacted with the part of the plurality of probes when an electrical current related abnormality occurs, to avoid the melting caused by the excessive current passing through due to abnormalities of the probes themselves, or the electrical test results being affected by the opening of the probes.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. A test device, comprising:
a guide plate structure;
a shunt structure coupled to the guide plate structure; and
a plurality of probes penetrating the guide plate structure and the shunt structure, in a manner that the shunt structure contacts with a part of the plurality of probes to provide a current shunting route.

2. The test device of claim 1, wherein a side of the guide plate structure is coupled to a circuit board, and another side is coupled to a device under test.

3. The test device of claim 1, wherein the guide plate structure includes a first guide plate and a second guide plate, and the first guide plate and the second guide plate are arranged in parallel with each other and are separated from each other by a gap.

4. The test device of claim 3, wherein a plurality of first openings are formed in the first guide plate, a plurality of second openings are formed in the second guide plate, and the plurality of first openings correspond in position to the plurality of second openings, respectively, to slidingly accommodate the plurality of probes.

5. The test device of claim 4, wherein each of the probes includes a stroke section, a test section and a switching section that extend from two sides of the stroke section.

6. The test device of claim 5, wherein the stroke section is located at the gap between the first guide plate and the second guide plate, and the stroke section is formed in a bent shape and thus has functions of absorbing external forces and stroke.

7. The test device of claim 5, wherein the test section extends from one end of the stroke section and passes through the first guide plate, so as to couple the test section to a device under test.

8. The test device of claim 5, wherein the switching section extends from the other end of the stroke section and passes through the second guide plate, so as to couple the switching section to a circuit board.

9. The test device of claim 3, wherein the shunt structure is disposed in the first guide plate or between the first guide plate and the second guide plate.

10. The test device of claim 9, wherein the shunt structure is defined with at least one first area and at least one second area, the at least one first area is an insulation material and has a plurality of first through holes, the at least one second area is a metal material and has a plurality of second through holes, and the plurality of probes are disposed through the plurality of first through holes and the plurality of second through holes.

11. The test device of claim 10, wherein the plurality of probes disposed through the plurality of the first through holes are used to test a signal, and the plurality of probes disposed through the plurality of second through holes are used to test a power.
